(19) United States
(12) Patent Application Publication
(10) Pub. No.: US 2014/0244604 A1
(43) Pub. Date: Aug. 28, 2014

(54) PREDICTING DATA COMPRESSIBILITY USING DATA ENTROPY ESTIMATION

(71) Applicant: MICROSOFT CORPORATION, Redmond, WA (US)

(72) Inventors: Paul Adrian Oltean, Redmond, WA (US); Cosmin A. Rusu, Kirkland, WA (US); Arnd Christian König, Kirkland, WA (US); Mark Steven Manasse, San Francisclo, CA (US); Jin Li, Bellevue, WA (US); Sudipta Sengupta, Redmond, WA (US); Sanjeev Mehrotra, Kirkland, WA (US)

(73) Assignee: MICROSOFT CORPORATION, Redmond, WA (US)

(21) Appl. No.: 13/781,663

(22) Filed: Feb. 28, 2013

(51) Int. Cl. H03M 7/30

(52) U.S. Cl. CPC H03M 7/30
USPC 707/693

(57) ABSTRACT

The subject disclosure is directed towards predicting compressibility of a data block, and using the predicted compressibility in determining whether a data block if compressed will be sufficiently compressible to justify compression. In one aspect, data of the data block is processed to obtain an entropy estimate of the data block, e.g., based upon distinct value estimation. The compressibility prediction may be used in conjunction with a chunking mechanism of a data deduplication system.

### BACKGROUND

Data compression is a useful technology that can save capacity on storage media and/or bandwidth over a network connection, as well as internal transfer time savings with bus and backplane data transfer. One application of data compression is in data optimization (sometimes referred to as data deduplication), which refers to reducing the physical amount of bytes of data that need to be stored on disk and/or transmitted across a network, without compromising the fidelity or integrity of the original data, i.e., the reduction in bytes is lossless and the original data can be completely recovered. In general, data deduplication chunks data and single-instances (deduplicates and saves) the unique chunks, which may be compressed chunks.

Thus, for saving data capacity, data compression may be used as an independent solution or integrated with a deduplication solution. Similarly, for saving network bandwidth, compression may be applied to the data being transferred. The data may be chunked using a chunking algorithm (e.g., in deduplication solutions) such that chunks already transferred need not be re-sent.

When used, compression is based upon an algorithm that typically involves significant computational resources and processing time. Different compression algorithms exist, and usually such compression algorithms provide different levels of compression relative to one another. In general, more compression savings (better compressibility) correlates with using a ‘heavier’ algorithm that takes more time to execute and/or consumes more computing (e.g., CPU) resources. Notwithstanding, even with a relatively “light” compression algorithm, compression usually takes significant time to execute and burdens the computing machine performing the compression.

Not all data compress the same. Different file types and different data types compress at different levels. As a result, compressing all data usually results in portions of the data that are compressed very little or not reduced at all by compression. This may be a large portion of the dataset, depending on the types of data in the dataset.

Therefore, compressing all data is likely to waste resources. The portion of data that does not compress well generates delay in storage and/or latency in data transfer, and uses up expensive computing resources without yielding any real benefit.

### SUMMARY

This Summary is provided to introduce a selection of representative concepts in a simplified form that are further described below in the Detailed Description. This Summary is not intended to identify key features or essential features of the claimed subject matter, nor is it intended to be used in any way that would limit the scope of the claimed subject matter.

Briefly, various aspects of the subject matter described herein are directed towards predicting compressibility of a data block, including by obtaining an entropy estimate corresponding to the data block. Data of the data block are processed to determine whether the entropy estimate of the data block is high. If the entropy estimate is not high, compressibility information is output that indicates that the data block is predicted to be sufficiently compressible.

In one aspect, a chunking mechanism of a deduplication system is configured to chunk data for storage in a chunk store. The chunking mechanism is coupled to or incorporates a compression prediction mechanism that processes at least some of the data in a chunk to obtain an estimate of compressibility of the chunk that is based upon data entropy estimation.

In one aspect, there is described estimating compressibility of a data block, including hashing at least some of the data of the data block into values in a data structure. The data structure is used to obtain an estimated data entropy of the data block, and the estimated data entropy used to determine whether to compress the data block.

Other advantages may become apparent from the following detailed description when taken in conjunction with the drawings.

### BRIEF DESCRIPTION OF THE DRAWINGS

The present invention is illustrated by way of example and not limited in the accompanying figures in which like reference numerals indicate similar elements and in which:

FIG. 1 is a block diagram representing example components/phases of an extensible pipeline used for data deduplication, in which the pipeline is configured to perform compressibility prediction via compressibility estimation, according to one example implementation.

FIG. 2 is a block diagram representing example components of a data storage service configured for data deduplication, including for compressibility estimation, according to one example implementation.

FIG. 3 is a block diagram representing example components configured for the estimation of compressibility, according to one example implementation.

FIG. 4 is a flow diagram representing example steps that may be take to perform compressibility prediction based upon compressibility estimation, according to one example implementation.

FIG. 5 is a block diagram representing exemplary non-limiting networked environments in which various embodiments described herein can be implemented.

FIG. 6 is a block diagram representing an exemplary non-limiting computing system or operating environment in which one or more aspects of various embodiments described herein can be implemented.

### DETAILED DESCRIPTION

Various aspects of the technology described herein are generally directed towards utilizing an efficient compressibility prediction mechanism (e.g., algorithm) to avoid compressing certain data of a dataset in which compression of that data is not likely to be productive. The prediction may be used to (typically) avoid compressing at least some of the data of a dataset, thereby significantly reducing the resources needed to compress the entire dataset, which in general increases storage subsystem ingestion of the data and/or reduces latency when transferring data over the wire. The compression prediction mechanism also may be used in selecting an appropriate compression algorithm, e.g., to use the prediction result as a hint for selecting an algorithm.

In one aspect, a relatively fast compression prediction mechanism is used to estimate the compressibility of data that corresponds to approximate entropy of the data. The compressibility estimate is generally based upon the number of distinct values in samples (e.g., eight-byte subsets) within the data. One or more hash functions are used to hash the data into values in a data structure set (one or more data structures), e.g., an array. The data structure set is processed to approximately estimate an amount of entropy of the data, which generally relates to the compressibility estimate.

In an example data deduplication system, the dataset is first chunked into chunks before any compression. Such chunking algorithms are usually faster and less CPU-extensive than compression. A compression prediction estimation mechanism may be incorporated into the chunking phase, which is already processing the data for chinking, whereby the compressibility estimation for a chunk may be implemented in only a relatively few extra instructions including in the chunking mechanism code.

It should be understood that any of the examples herein are non-limiting. For instance, many of the examples herein are generally described in a data deduplication environment, which may be implemented as an extensible pipeline; however benefits may be obtained via the technology described herein in any environment where a compressibility prediction may be of use, including non-deduplication/non-pipeline scenarios. As such, the present invention is not limited to any particular embodiments, aspects, concepts, structures, functionalities or examples described herein. Rather, any of the embodiments, aspects, concepts, structures, functionalities or examples described herein are non-limiting, and the present invention may be used various ways that provide benefits and advantages in data processing, data communication, data storage and/or the like in general.

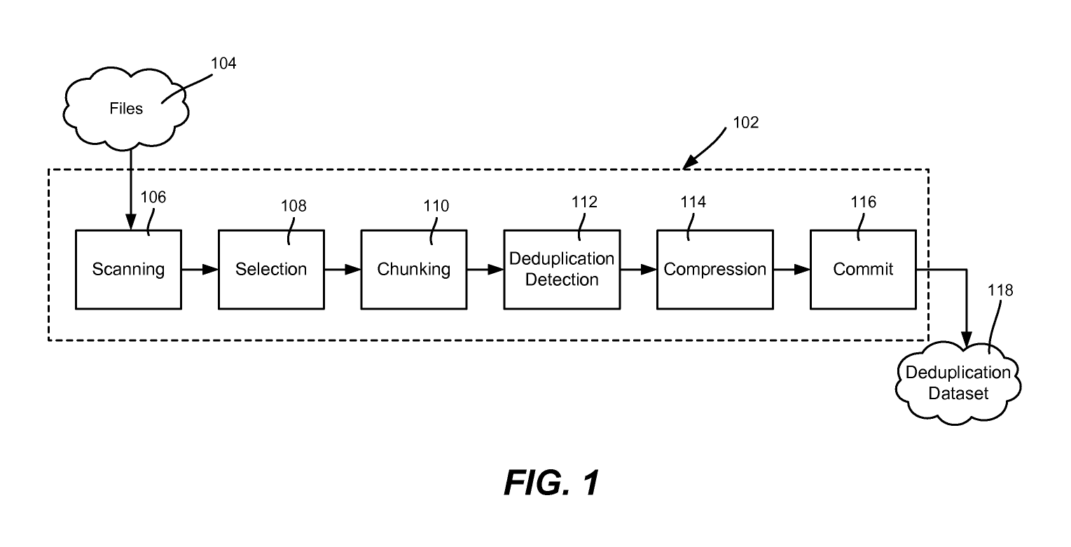

FIG. 1 shows example phases of a data deduplication pipeline 102, comprising software phases (via a set of components) that handles the process of deduplication of files 104. Note that while files are used as one example herein, the deduplication target may comprise any collection of “data streams” in an unstructured, semi-structured or structured data storage environment, e.g., files, digital documents, streams, blobs, tables, databases, and so forth; the pipeline architecture is generic and reusable across a large variety of data stores. Thus, while predicting/estimating the compressibility of a chunk is used as an example, any arbitrary set of data, referred to herein as a “data block” for brevity, may be compressed or not based upon the compressibility prediction.

As described herein, the exemplified pipeline 102 comprises a number of phases, corresponding to extensible and/or selectable modules. Further, the modules (generally other than for deduplication detection) may operate in parallel, e.g., to facilitate load balancing. The pipeline architecture also provides isolation for crash resistance, security and resource management.

In general, deduplication splits each file (or other data blob) into a consecutive sequence of small data streams (called chunks), and then for each chunk, uniquely identifies each chunk using a hash value obtained via a hash function. Deduplication then performs a lookup (via a hash index) for the existence of a duplicate chunk that was previously inserted in the system. When a duplicate chunk is detected, the specific region in the file corresponding to the original chunk is updated with a reference to the existing chunk and the chunk from the file discarded. If a duplicate is not detected, the chunk is saved to a chunk store in one implementation (or other suitable location), indexed, and the file updated with a reference to the new chunk, which may then be detected for referencing by other files. The pipeline also may perform compression of the chunks, which may be selective compression as described herein.

To track the chunks, each file contains references to its chunks that are stored into the system, along with their position in the current file, instead of the file data, which consumes far less storage when multiple files reference the same chunk or chunks. In one implementation, the file is replaced with a sparse file (if not already a sparse file) having a reparse point and/or stream that references the corresponding chunk data. The reparse point and/or stream contain enough information to allow the reconstruction of its corresponding file data during subsequent I/O servicing. Alternative implementations to link files with their corresponding chunks are feasible.

The pipeline 102 includes data-related phases, implemented as one or more modules per phase. This may include a scanning phase 106 that scans a dataset to determine which ones are candidates for deduplication, generally those not already deduplicated. Other policy and/or criteria may be used, such as to not “specially treat” encrypted files, for example, because such files may seldom if ever have a chunk that will match another file's chunk. The scanning phase's output basically comprises a list of files that is dynamically consumed by the next phase of the deduplication pipeline, comprising a selection phase 108.

Scanning 106 thus may identify files to be optimized in an optimization session, generally those not yet deduplicated, to output the list that is dynamically consumed by the rest of the pipeline. File streaming interfaces for file stream access may be provided to provide secure access to the file content, e.g., for use in chunking and compression modules as described below; (note that chunking/hashing/compression modules may not have direct access to the file system (and may not be tied with file system features at all), whereby such modules may have access via a set of streaming interfaces that provide a virtualized access to the file stream).

In general, the selection phase 108 filters, sorts and/or prioritizes (ranks) the candidates, so that, for example, the ones most likely to yield high deduplication gains may be processed first through the pipeline. Files also may be grouped to facilitate efficient processing and/or to enable optimal selection of the most appropriate modules to be used in further stages of the pipeline. File properties such as file name, type, attributes, location on the disk, and so forth, and/or statistical property data such as frequency of file operations over time may be used to determine the policy for the selection phase 108. In general, the scanning phase 106 and selection phase 108 (file selector/filtering and so forth) generally work together according to policy-driven criteria before feeding files to the rest of the pipeline.

A chunking phase 110 takes the data (e.g., a list of files) to be deduplicated and separates them into chunks. As part of this processing, a stream of data is input and evaluated to find a suitable chunk boundary. When a chunk is determined, the chunk provides the data to a deduplication detection phase 112, which determines (often via a cryptographically secure hash function to obviate attacks) whether the chunk already exists in the deduplication dataset 118. If the chunk is a new chunk, compression may occur in a compression phase 114 before a commit phase 116 commits the chunk to the deduplication dataset 118.

As described herein, selective compression (e.g., compression may or may not occur) is based upon a compressibility prediction determined by estimating from the data block (e.g., a chunk) whether the approximate data entropy is too high to likely compress well. Further, if compression is to be performed, the compression algorithm that is used may be selected based upon a hint from the approximate entropy estimation. Note that other hints may be used if known, e.g., the type of the data if the file type is known and/or certain structuring of the data is recognizable, and so forth.

Note that while compression prediction (and/or entropy estimation) may be performed at the chunk level as exemplified herein, the described operations instead may be done on data segments that may or may not align with chunk boundaries. More generally, entropy estimation may be performed on any “areas” (i.e., segments) of data, e.g., based upon an assumption is that there is some locality aspect for the entropy; e.g., if a particular range has a certain level of compressibility (high or low), then it is likely that a subsequent range of bytes also has a similar compressibility level and likely similar data entropy. By way of example, if chunk sizes are 4 KB on average, and entropy samples are taken every 32 KB, the entropy of each 4 KB chunk may be interpolated from two entropy samples via an interpolation process (constant, or linear, polynomial, moving average, and so forth). Thus, the compressibility of a chunk may be inferred based on interpolation or extrapolation of sampled entropy.

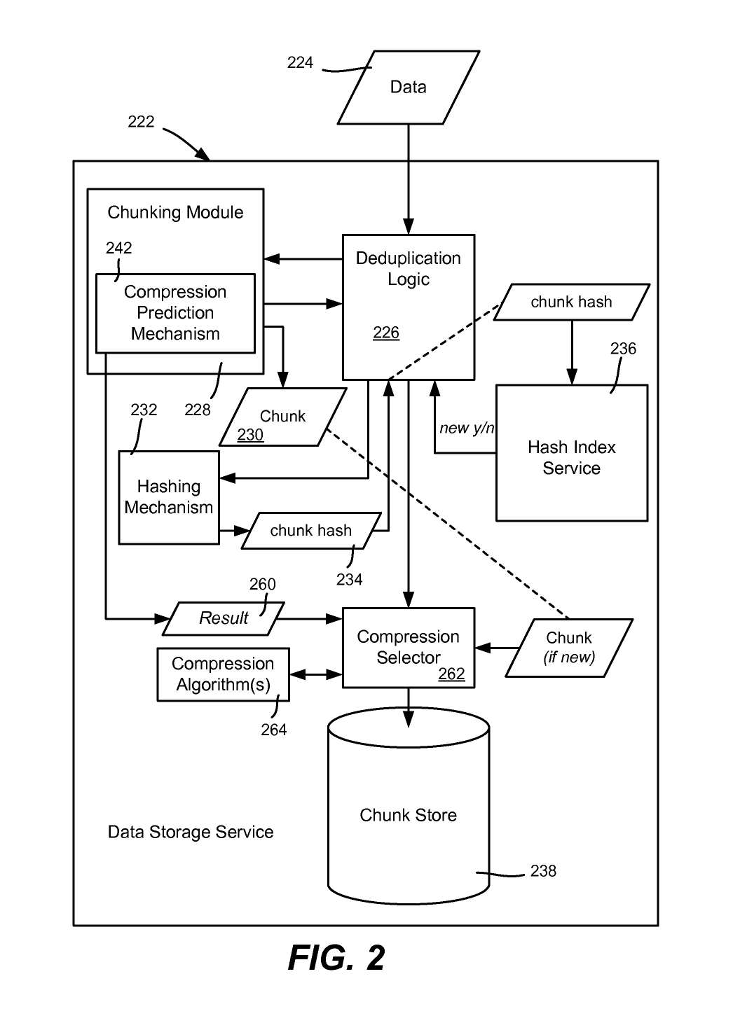

In general, FIG. 2 shows example components of a data deduplication data storage system, such as implemented in a data/file storage service 222. The service 222 receives data 224 (a file, blob, or the like), and deduplication logic 226 processes/manages the data flow for deduplication. To this end, the deduplication logic 226 provides the data 224 to a chunking module 228, which processes the content into chunks, such as according to the structure of the file (e.g., partition a media file into a media header and media body), or by using an algorithm to chunk the file contents based on fast hashing techniques (such fast hash functions include CRC and Rabin families of functions) that is repeatedly computed on a sliding window, where a chunk is being selected when the hash functions and the current chunk size/content meet certain heuristics. A chunk boundary is generally determined in a data-dependant fashion at positions for which the hash function satisfies a certain condition. Note that some of the example description is with respect to one chunk 230, although it is understood that the data is typically partitioned into multiple chunks.

The deduplication logic 226 passes the chunk 230 to a hashing mechanism 232, which computes a hash of the chunk, referred to as the chunk hash 234. A strong hash function, e.g., MDS or a cryptographically secure SHA-256 or SHA-512 hash function or the like (one which ensures an extremely low probability of collisions between hashes) may be used as the chunk hash 234 that uniquely identifies the chunk 230.

The chunk hash 234 is provided to a hash index service 236. If the chunk hash 234 is found (that is, already exists) in the hash index service 236, a duplicate copy of the chunk 230 is considered to have been already deposited in the chunk store 238, and the current chunk need not to be further stored. Instead, any reference to this chunk may simply refer to the prior, existing chunk in the chunk store 238. Note that while a duplicate chunk need not be stored again, nor recompressed if already stored in a compressed state, deduplication (and/or compressibility prediction) processing may be used to consider whether compression (if uncompressed) or another level of compression (if compressed) may be more productive in terms of the current chunk size. Thus, another implementation may further process a chunk that already exists in the chunk store with respect to compressibility considerations.

If the chunk hash 234 is not found in the hash index service 236, the chunk 230 is deposited into the chunk store 238, and the chunk hash 234 is deposited into the hash index service 236. As can be readily appreciated, given enough data over time, a great deal of storage may be saved by referencing a chunk instead of maintaining many separate instances of the same chunk of data.

Moreover, before storing a chunk in the chunk store and/or transmitting over a network connection, chunks are often compressed, saving even more storage/bandwidth; note that the hashes may be computed on the uncompressed chunks before compression, and/or hashes may be computed after compression. However, as set forth above, not all chunks or other data benefit from compression, at least not sufficiently to justify compression, and thus in one implementation the hash is computed before compression.

Described herein is processing the data to estimate approximate data entropy, which generally corresponds to whether the data is likely to be sufficiently compressible to justify performing compression, (as high entropy generally corresponds to poor compressibility). As will be understood, this processing of the data is in contrast to other techniques that actually perform compression (on at least some of the data) to determine whether compression is worthwhile and/or which compression algorithm to use. As also will be understood, the processing of the data does not compute a relatively precise entropy of the data, but rather computes an approximate estimate of whether the entropy of the data is high, which is significantly less resource-insensitive and complex than determining a relatively precise entropy value. For example, if determining whether or not to compress at all, the way that the approximate entropy estimate is used as described herein is generally unconcerned with anything other than whether the entropy is high, and indeed, distinguishing among various lower entropy levels is immaterial and unnecessary for this purpose. One technique that provides for adequate approximate estimations of high data entropy versus not high data entropy is based upon distinct value estimation.

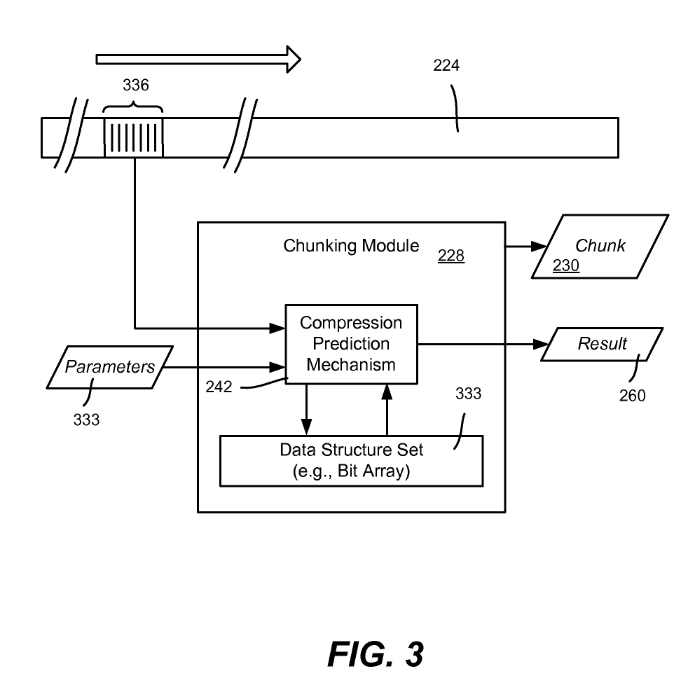

FIGS. 2 and 3 generally represent on way in which the compressibility estimate processing may be performed, in which the data 224 to be processed (e.g., a stream corresponding to file data) is input into a compression prediction mechanism 242 that operates based upon distinct value estimation. In general, the compressibility of data/approximate data entropy (if around high levels) corresponds to how many distinct instances of values exist within the data. The size of the values, which may be referred to as a sample size, may be a configurable parameter (comprising a number of bytes or bits of the data) among one or more manually and/or programmatically configured configurable parameters 333 (FIG. 3).

In the example of FIGS. 2 and 3, the compression prediction mechanism 224 is shown as being incorporated into the chunking module 228, which is advantageous in at least some deduplication scenarios because the data 224 is already being processed for chunking purposes, and thus resides in memory, for example. Notwithstanding, the compression prediction mechanism 332 may operate independent of any deduplication and/or chunking concepts. For example, a file or other data blob to be transferred over the network may be processed to estimate whether performing compression is likely to be worthwhile; the configurable parameters for such a file may be selected based upon file type, file size, network state, and so forth.

In one implementation, as represented in FIGS. 2 and 3, the compression prediction mechanism 242 takes a value 336 of size sample (e.g., eight bytes) as input, and hashes the value via a hash function to map it to an indexed bin in a data structure set 336, such as a bit location in a bit array. Note that a bit array is only one type of data structure that may be used, and it is understood that other types of data structures may be used, and/or that a plurality of data structures, of the same type and/or different types, may be used. For example, one data structure may be arranged as relatively small (e.g., three-bit) counters corresponding to hash-indexed locations, with the appropriate indexed counter incremented when a value hashes to that counter location, with capping or divide-by-two (shift right) counter overflow prevention used.

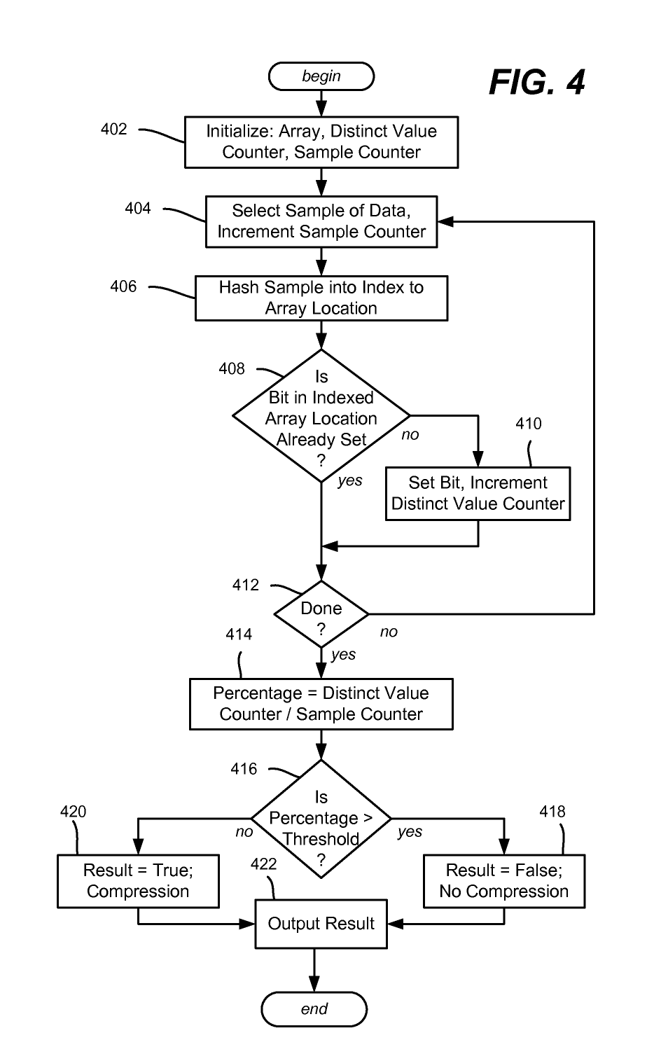

However, when used with a typically-sized chunk (e.g., 64 KB) and suitable (e.g., 8-byte) sample values, a bit array data structure (e.g., 4 KB) and corresponding hash function is advantageous in one implementation. This is because acceptably accurate prediction results may be obtained with a bit array that fits within the L1 processor cache, facilitating extremely fast processing. Note however that the size of the array may be based upon the chunk size for chunks, a file size for files, or some other configurable maximum set so that the bitmap size is appropriate for the number of samples. In any event, a bit array is described in the example of FIG. 4.

FIG. 4 shows the distinct value estimation operation as example steps, beginning at step 402 where the bit array, distinct value counter and sample counter are each initialized (e.g., to zero). Step 404 selects a sample of data and increments the sample counter so that the total number of samples processed is known, e.g., to determine what percentage of the total samples are distinct values as described below.

Note that the sampling may be uniform or non-uniform, such as generated by picking sampling points using a random number generator or the like. Further, different sampling frequencies may be used. The sample may be a window that is advanced one byte at a time, for example, or a larger amount, based upon a sampling parameter. For example, not all data of an arbitrary data block to be processed, such as a chunk, need be evaluated to obtain an estimate of compressibility, in which case the sampling parameter (frequency) may be set to skip over some data. External data such as file type, data size and so forth may be used as factors in determining a suitable window (sample) size parameter and sampling parameter for a data block.

Moreover, as another example, the compressibility of a large or other given dataset may be predicted, such as by sampling all or some part of the data, with the result used to determine whether any of that dataset is to be compressed at all. For example, instead of predicting compression for each chunk, a dataset that is to be chunked into a number of chunks may be evaluated as a data block with respect to predicting compressibility. If that data block is deemed likely to not compress well, then compression may be avoided for the entire dataset, or some part thereof. Conversely, if deemed likely to compress well, then compression may be used with the whole dataset or with subset data blocks of the entire dataset, or further compressibility prediction may be individually performed on any or all subset data blocks, e.g., on each chunk of a larger dataset being chunked.

Step 406 hashes the sample into an array index/location. If at step 408 the bit value at the hash-computed location is still zero as initialized at step 402, then as will be understood, this value (this sample) in the data has not been seen before (is distinct so far in the stream processing). Because distinct values are used in the entropy/compressibility estimation, at step 410 the bit at this array location is set to one, and the distinct value counter incremented. Conversely, if the hashed value had been seen before, step 408 detects that the bit is already set equal to one at this location, whereby step 410 is bypassed such that the data structure is left unchanged and the distinct value counter is not incremented. Note that the distinct value counter thus tracks the total number of bits that are set in the array, with setting of a bit only occurring the first time the hash function indexes a value to that bit location.

Step 412 repeats the above process for the next value, and so on, until the streamed data is done being processed.

At step 414, in this example a percentage is computed based upon the distinct value counter of set bits in the array divided by the number of samples as tracked by the sample counter. If at step 416 this percentage achieves a threshold value, e.g., is greater than a configurable threshold parameter, then the approximated data entropy is deemed too high, and the result to return is set to false at step 418 so as to not compress the data. If not too high, at step 420 the result to return is set to true so that compression will be attempted. Step 422 outputs the result, which, for example, may be the result 260 in FIGS. 2 and 3 that is output from the compression prediction mechanism 242.

FIGS. 2 and 3 show usage of the result 260, namely being fed as input to a compression selector 262. If the result 260 is false, the compression selector 262 selects no compression as the selection, and the chunk 230 will be committed in the chunk store 238 uncompressed. If true, the compression selector 262 selects a compression algorithm (possibly based on other selection criteria) from among one or more compression algorithms 264, and compresses the chunk for committing to the chunk store 238 as a compressed chunk.

Returning to the use of a hash function to efficiently identify distinct values, it is possible that the hash function may map two distinct values to the same location, that is, a hash collision occurs. The various parameters including the array size, sample size, sampling and/or the threshold value that the distinct value counter needs to reach to be considered “high” and so forth may be tuned to reduce the impact of such hash collisions.

Another technique to reduce the effect of hash collisions is to input each value into more than one hash function, (e.g., k hash functions at step 406 of FIG. 4) may be used, whereby any two distinct values are far less likely to map to the same k locations in the array. This is basically a Bloom filter that maps each input value to k locations. As with other aspects described herein, the various parameters may be tuned to compensate for the number of hash functions used. Bloomier filters also may be used to accumulate the entropy-related/distinct value data, and indeed, any structure that holds an approximation of accumulated information may be used.

While FIG. 4 showed simplified example steps of one implementation, various other steps may be used, such as to disable compression via a setting, or bypass the steps of FIG. 4 and simply compress if the sample (window size) is set greater than the chunk size. The following describes some example parameters that may be used, with example values in parentheses:

#define CHUNK_ENTROPY_BIT_ARRAY_SIZE (32*1024) // bit array size in bits
#define CHUNK_ENTROPY_WINDOW_SIZE (4) // sliding window size in bytes
#define CHUNK_ENTROPY_THRESHOLD (0.95) // chunk entropy threshold
#define CHUNK_ENTROPY_SAMPLING (64) // sampling
#define CHUNK_ENTROPY_BIT_MASK (0x7fff) // log 2(bit array size)

It should be noted that the compressibility hint based upon approximate entropy estimation may be used in various ways, including in a data deduplication pipeline as in FIGS. 1 and 2, where compression may or may not occur before committing the chunk to the chunk store. For example, compression may be deferred. For example, chunks to be compressed may be differentiated in some way from those to not be compressed, such as via metadata, or having chunks to be compressed committed to one chunk store, and chunks not to be compressed committed to another chunk store. Further processing may be done at a later time, e.g., compression may occur on the files to be compressed in the one chunk store when convenient, possibly using dedicated compression hardware chips and the like.

Similarly, a chunk with a “not high” approximate entropy estimate may be compressed with a relatively “light” compression algorithm into a chunk store, e.g., via processing through the pipeline of FIGS. 1 and 2. More extensive compression via other algorithms may be performed on these chunks at a later time, e.g., using various techniques such as trial and error, using media type as a hint, using the initial “light” compression ratio to determine candidates for further compression processing, and so forth.

One factor that may be used in determining a candidate may include the compressibility estimate as described above. For example, although the above-described compressibility estimate based upon distinct value estimation is good at distinguishing high entropy approximations versus not-high entropy approximations, and not necessarily good at distinguishing between levels below high entropy approximations, at times lower entropy level distinction may give a hint as to whether further, “heavier” compression may provide benefits. For example, for a “medium” level chunk or file compressibility estimate, Huffman encoding plus LZ77 compression may be used, whereas for a lower level compressibility estimate, only LZ77 may be used. In this way, selective compression based upon the compressibility estimate may be more fine-grained than only for turning compression on or off for data.

Another aspect may consider the “order of entropy” used in the entropy estimation. For example, a “heavier” compression algorithm may be able to achieve better compression relative to a “lighter” one because the heavier one looks at multiple symbols in aggregate; because higher order entropy (looking at multiple symbols in aggregate and normalized to per symbol) is lower than a lower order one, these compression schemes can achieve savings when other cannot. As a simplified example, with a data stream of “ABABABAB . . . ,” looking at one symbol at a time has an entropy of one bit/symbol. If looking at two symbols at a time, then the entropy is essentially zero.

Various entropies may be estimated (e.g., each looking at a certain number of symbols in aggregate). Based on the estimations, an appropriate compression scheme may be chosen. For example, if lower order entropies are already very small, then a simple lightweight compression scheme can be used. Thus, one or more entropy estimates may be used to decide on a compression scheme.

### Exemplary Networked and Distributed Environments

One of ordinary skill in the art can appreciate that the various embodiments and methods described herein can be implemented in connection with any computer or other client or server device, which can be deployed as part of a computer network or in a distributed computing environment, and can be connected to any kind of data store or stores. In this regard, the various embodiments described herein can be implemented in any computer system or environment having any number of memory or storage units, and any number of applications and processes occurring across any number of storage units. This includes, but is not limited to, an environment with server computers and client computers deployed in a network environment or a distributed computing environment, having remote or local storage.

Distributed computing provides sharing of computer resources and services by communicative exchange among computing devices and systems. These resources and services include the exchange of information, cache storage and disk storage for objects, such as files. These resources and services also include the sharing of processing power across multiple processing units for load balancing, expansion of resources, specialization of processing, and the like. Distributed computing takes advantage of network connectivity, allowing clients to leverage their collective power to benefit the entire enterprise. In this regard, a variety of devices may have applications, objects or resources that may participate in the resource management mechanisms as described for various embodiments of the subject disclosure.

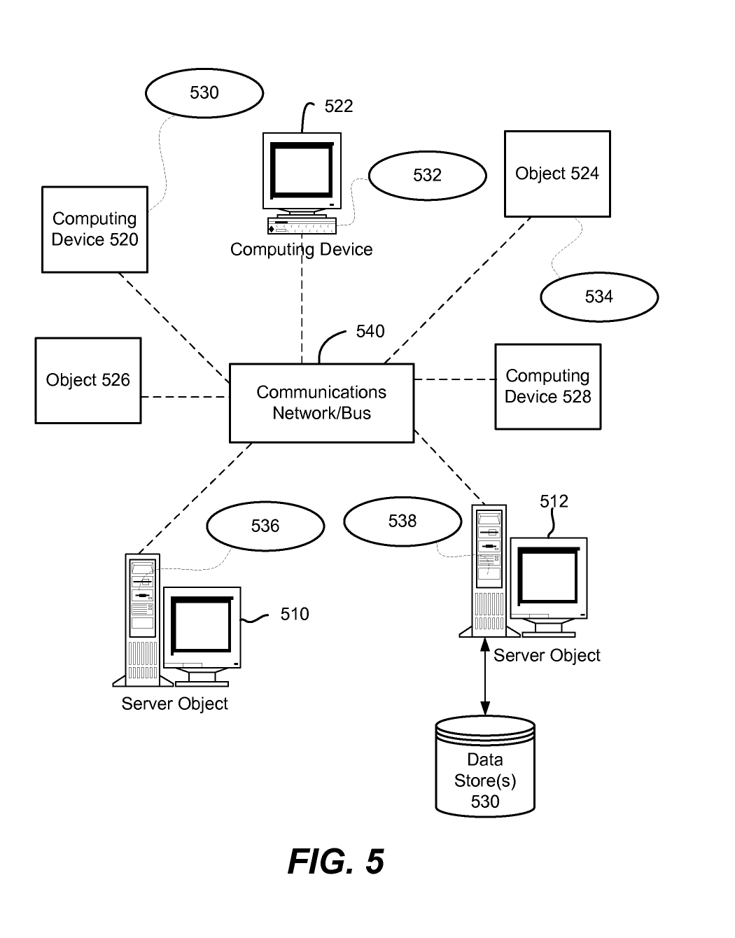

FIG. 5 provides a schematic diagram of an exemplary networked or distributed computing environment. The distributed computing environment comprises computing objects 510, 512, etc., and computing objects or devices 520, 522, 524, 526, 528, etc., which may include programs, methods, data stores, programmable logic, etc. as represented by example applications 530, 532, 534, 536, 538. It can be appreciated that computing objects 510, 512, etc. and computing objects or devices 520, 522, 524, 526, 528, etc. may comprise different devices, such as personal digital assistants (PDAs), audio/video devices, mobile phones, MP3 players, personal computers, laptops, etc.

Each computing object 510, 512, etc. and computing objects or devices 520, 522, 524, 526, 528, etc. can communicate with one or more other computing objects 510, 512, etc. and computing objects or devices 520, 522, 524, 526, 528, etc. by way of the communications network 540, either directly or indirectly. Even though illustrated as a single element in FIG. 5, communications network 540 may comprise other computing objects and computing devices that provide services to the system of FIG. 5, and/or may represent multiple interconnected networks, which are not shown. Each computing object 510, 512, etc. or computing object or device 520, 522, 524, 526, 528, etc. can also contain an application, such as applications 530, 532, 534, 536, 538, that might make use of an API, or other object, software, firmware and/or hardware, suitable for communication with or implementation of the application provided in accordance with various embodiments of the subject disclosure.

There are a variety of systems, components, and network configurations that support distributed computing environments. For example, computing systems can be connected together by wired or wireless systems, by local networks or widely distributed networks. Currently, many networks are coupled to the Internet, which provides an infrastructure for widely distributed computing and encompasses many different networks, though any network infrastructure can be used for exemplary communications made incident to the systems as described in various embodiments.

Thus, a host of network topologies and network infrastructures, such as client/server, peer-to-peer, or hybrid architectures, can be utilized. The “client” is a member of a class or group that uses the services of another class or group to which it is not related. A client can be a process, e.g., roughly a set of instructions or tasks, that requests a service provided by another program or process. The client process utilizes the requested service without having to “know” any working details about the other program or the service itself.

In a client/server architecture, particularly a networked system, a client is usually a computer that accesses shared network resources provided by another computer, e.g., a server. In the illustration of FIG. 5, as a non-limiting example, computing objects or devices 520, 522, 524, 526, 528, etc. can be thought of as clients and computing objects 510, 512, etc. can be thought of as servers where computing objects 510, 512, etc., acting as servers provide data services, such as receiving data from client computing objects or devices 520, 522, 524, 526, 528, etc., storing of data, processing of data, transmitting data to client computing objects or devices 520, 522, 524, 526, 528, etc., although any computer can be considered a client, a server, or both, depending on the circumstances.

A server is typically a remote computer system accessible over a remote or local network, such as the Internet or wireless network infrastructures. The client process may be active in a first computer system, and the server process may be active in a second computer system, communicating with one another over a communications medium, thus providing distributed functionality and allowing multiple clients to take advantage of the information-gathering capabilities of the server.

In a network environment in which the communications network 540 or bus is the Internet, for example, the computing objects 510, 512, etc. can be Web servers with which other computing objects or devices 520, 522, 524, 526, 528, etc. communicate via any of a number of known protocols, such as the hypertext transfer protocol (HTTP). Computing objects 510, 512, etc. acting as servers may also serve as clients, e.g., computing objects or devices 520, 522, 524, 526, 528, etc., as may be characteristic of a distributed computing environment.

### Exemplary Computing Device

As mentioned, advantageously, the techniques described herein can be applied to any device. It can be understood, therefore, that handheld, portable and other computing devices and computing objects of all kinds are contemplated for use in connection with the various embodiments. Accordingly, the below general purpose remote computer described below in FIG. 8 is but one example of a computing device.

Embodiments can partly be implemented via an operating system, for use by a developer of services for a device or object, and/or included within application software that operates to perform one or more functional aspects of the various embodiments described herein. Software may be described in the general context of computer executable instructions, such as program modules, being executed by one or more computers, such as client workstations, servers or other devices. Those skilled in the art will appreciate that computer systems have a variety of configurations and protocols that can be used to communicate data, and thus, no particular configuration or protocol is considered limiting.

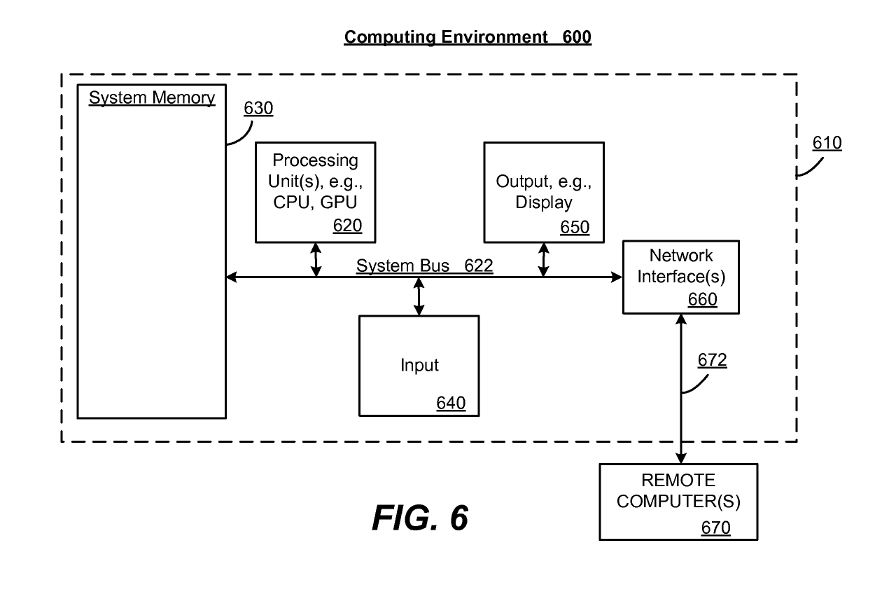

FIG. 6 thus illustrates an example of a suitable computing system environment 600 in which one or aspects of the embodiments described herein can be implemented, although as made clear above, the computing system environment 600 is only one example of a suitable computing environment and is not intended to suggest any limitation as to scope of use or functionality. In addition, the computing system environment 600 is not intended to be interpreted as having any dependency relating to any one or combination of components illustrated in the exemplary computing system environment 600.

With reference to FIG. 6, an exemplary remote device for implementing one or more embodiments includes a general purpose computing device in the form of a computer 610. Components of computer 610 may include, but are not limited to, a processing unit 620, a system memory 630, and a system bus 622 that couples various system components including the system memory to the processing unit 620.

Computer 610 typically includes a variety of computer readable media and can be any available media that can be accessed by computer 610. The system memory 630 may include computer storage media in the form of volatile and/or nonvolatile memory such as read only memory (ROM) and/or random access memory (RAM). By way of example, and not limitation, system memory 630 may also include an operating system, application programs, other program modules, and program data.

A user can enter commands and information into the computer 610 through input devices 640. A monitor or other type of display device is also connected to the system bus 622 via an interface, such as output interface 650. In addition to a monitor, computers can also include other peripheral output devices such as speakers and a printer, which may be connected through output interface 650.

The computer 610 may operate in a networked or distributed environment using logical connections to one or more other remote computers, such as remote computer 670. The remote computer 670 may be a personal computer, a server, a router, a network PC, a peer device or other common network node, or any other remote media consumption or transmission device, and may include any or all of the elements described above relative to the computer 610. The logical connections depicted in FIG. 6 include a network 672, such local area network (LAN) or a wide area network (WAN), but may also include other networks/buses. Such networking environments are commonplace in homes, offices, enterprise-wide computer networks, intranets and the Internet.

As mentioned above, while exemplary embodiments have been described in connection with various computing devices and network architectures, the underlying concepts may be applied to any network system and any computing device or system in which it is desirable to improve efficiency of resource usage.

Also, there are multiple ways to implement the same or similar functionality, e.g., an appropriate API, tool kit, driver code, operating system, control, standalone or downloadable software object, etc. which enables applications and services to take advantage of the techniques provided herein. Thus, embodiments herein are contemplated from the standpoint of an API (or other software object), as well as from a software or hardware object that implements one or more embodiments as described herein. Thus, various embodiments described herein can have aspects that are wholly in hardware, partly in hardware and partly in software, as well as in software.

The word “exemplary” is used herein to mean serving as an example, instance, or illustration. For the avoidance of doubt, the subject matter disclosed herein is not limited by such examples. In addition, any aspect or design described herein as “exemplary” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used, for the avoidance of doubt, such terms are intended to be inclusive in a manner similar to the term “comprising” as an open transition word without precluding any additional or other elements when employed in a claim.

As mentioned, the various techniques described herein may be implemented in connection with hardware or software or, where appropriate, with a combination of both. As used herein, the terms “component,” “module,” “system” and the like are likewise intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on computer and the computer can be a component. One or more components may reside within a process and/or thread of execution and a component may be localized on one computer and/or distributed between two or more computers.

The aforementioned systems have been described with respect to interaction between several components. It can be appreciated that such systems and components can include those components or specified sub-components, some of the specified components or sub-components, and/or additional components, and according to various permutations and combinations of the foregoing. Sub-components can also be implemented as components communicatively coupled to other components rather than included within parent components (hierarchical). Additionally, it can be noted that one or more components may be combined into a single component providing aggregate functionality or divided into several separate sub-components, and that any one or more middle layers, such as a management layer, may be provided to communicatively couple to such sub-components in order to provide integrated functionality. Any components described herein may also interact with one or more other components not specifically described herein but generally known by those of skill in the art.

In view of the exemplary systems described herein, methodologies that may be implemented in accordance with the described subject matter can also be appreciated with reference to the flowcharts of the various figures. While for purposes of simplicity of explanation, the methodologies are shown and described as a series of blocks, it is to be understood and appreciated that the various embodiments are not limited by the order of the blocks, as some blocks may occur in different orders and/or concurrently with other blocks from what is depicted and described herein. Where non-sequential, or branched, flow is illustrated via flowchart, it can be appreciated that various other branches, flow paths, and orders of the blocks, may be implemented which achieve the same or a similar result. Moreover, some illustrated blocks are optional in implementing the methodologies described hereinafter.

### CONCLUSION

While the invention is susceptible to various modifications and alternative constructions, certain illustrated embodiments thereof are shown in the drawings and have been described above in detail. It should be understood, however, that there is no intention to limit the invention to the specific forms disclosed, but on the contrary, the intention is to cover all modifications, alternative constructions, and equivalents falling within the spirit and scope of the invention.

In addition to the various embodiments described herein, it is to be understood that other similar embodiments can be used or modifications and additions can be made to the described embodiment(s) for performing the same or equivalent function of the corresponding embodiment(s) without deviating therefrom. Still further, multiple processing chips or multiple devices can share the performance of one or more functions described herein, and similarly, storage can be effected across a plurality of devices. Accordingly, the invention is not to be limited to any single embodiment, but rather is to be construed in breadth, spirit and scope in accordance with the appended claims.

What is claimed is:

1. In a computing environment, a method, comprising, processing data of a data block to predict compressibility of the data block, including obtaining an entropy estimate corresponding to the data block, determining whether the entropy estimate of the data block is high, and if not, outputting compressibility information that indicates that the data block is predicted to be sufficiently compressible.

2. The method of claim 1 wherein obtaining the entropy estimate comprises estimating a number of distinct values in the data block, and wherein determining whether the entropy estimate of the data block is high comprises evaluating the number of distinct values against a threshold level.

3. The method of claim 2 wherein estimating the number of distinct values comprises performing at least one hash function on at least some of the data of the data block to obtain the number of distinct values.

4. The method of claim 1 further comprising, obtaining the entropy estimate by generating hash values via a plurality of hash functions on at least some of the data of the data block, maintaining representations of the hash values, and processing the representations of the hash values to estimate the number of distinct values in the data block.

5. The method of claim 4 wherein maintaining representations of the hash values comprises maintaining a structure that holds an approximation of accumulated information.

6. The method of claim 1 wherein obtaining the entropy estimate of the data block comprises sampling less than all of the data of the data block.

7. The method of claim 1 wherein obtaining the entropy estimate of the data block comprises performing uniform sampling or non-uniform sampling, or a combination of uniform sampling and non-uniform sampling.

8. The method of claim 1 wherein obtaining the entropy estimate of the data block comprises inferring the compressibility of a chunk based on interpolation or extrapolation of sampled entropy.

9. The method of claim 1 further comprising, determining sampling parameters based at least in part on a file format.

10. The method of claim 1 further comprising, selecting a compression algorithm or no compression based at least in part upon the compressibility information.

11. In a computing environment, a system comprising, a chunking mechanism of a deduplication system, the chunking mechanism configured to chunk data for storage in a chunk store, the chunking mechanism coupled to or incorporating a compression prediction mechanism, the compression prediction mechanism configured to process at least some of the data in a chunk to obtain an estimate of compressibility of the chunk based upon a data entropy estimation.

12. The system of claim 11 wherein the compression prediction mechanism performs entropy estimation based upon distinct value estimation via at least one hash algorithm that hashes the at least some of the data in the chunk into representative values maintained in at least one data structure, and wherein the compression prediction mechanism uses the representative values in each data structure to obtain the estimate of compressibility of the chunk.

13. The system of claim 12 wherein at least one data structure comprises a bitmap, Bloom filter or Bloomier filter.

14. The system of claim 11 wherein the deduplication system includes a compression mechanism that compresses the chunk if the estimate of the compressibility of the chunk achieves a threshold value.

15. The system of claim 14 wherein the compression mechanism uses the estimate of the compressibility of the chunk at least in part as a hint to select a compression algorithm.

16. One or more computer-readable media having computer-executable instructions, which when executed perform steps, comprising, estimating compressibility of a data block, including hashing at least some of the data of the data block into values in a data structure, using the data structure to obtain an estimated data entropy of the data block, and using the estimated data entropy to determine whether to compress the data block.

17. The one or more computer-readable media of claim 16 having further computer-executable instructions comprising, determining from the estimated data entropy that the data block is to be compressed, and compressing the data block.

18. The one or more computer-readable media of claim 17 having further computer-executable instructions comprising, using the estimated data entropy, and zero or more other estimated data entropies, as at least one factor in selecting a compression algorithm for compressing the data block.

19. The one or more computer-readable media of claim 16 wherein using the data structure to obtain an estimated data entropy of the data block comprises tracking distinct values in the data structure, and using a count of the distinct values relative as part of obtaining estimated data entropy.

20. The one or more computer-readable media of claim 16 having further computer-executable instructions comprising sampling data in the data block based upon a sliding window size parameter and a sampling parameter.
